(19) United States
(12) Patent Application Publication
(10) Pub. No.: US 2026/0031788 A1
(43) Pub. Date: Jan. 29, 2026

(54) QUARTZ CRYSTAL DEVICE, QUARTZ-CRYSTAL VIBRATING PIECE, AND CRYSTAL WAFER

(71) Applicant: NIHON DEMPA KOGYO CO., LTD., Tokyo (JP)

(72) Inventor: Tetsuya WATANABE, Saitama (JP)

(73) Assignee: NIHON DEMPA KOGYO CO., LTD., Tokyo (JP)

(21) Appl. No.: 19/267,626

(22) Filed: Jul. 13, 2025

(30) Foreign Application Priority Data
Jul. 25, 2024 (JP) 2024-119264

(51) Int. Cl. H03H 9/19; H03H 3/02; H03H 9/10; H03H 9/13

(52) U.S. Cl. CPC H03H 9/19; H03H 3/02; H03H 9/1021; H03H 9/132

(57) ABSTRACT

A quartz crystal device includes a package, an AT-cut quartz-crystal vibrating piece, and a securing member. The package includes a bottom plate in a rectangular shape in plan view, a dike provided along an edge of the bottom plate, and an adhesion pad provided on one end side in a long-side direction in an inner region surrounded by the dike. The quartz-crystal vibrating piece includes an excitation electrode, a pad electrode positioned on one end side in a long-side direction thereof, and an extraction electrode connecting the excitation electrode to the pad electrode. The securing member secures the quartz-crystal vibrating piece to the adhesion pad at a position where the pad electrode is opposed to the adhesion pad. A ratio of a width of the extraction electrode to a dimension in a short-side direction of the quartz-crystal vibrating piece is 15% or more and less than 50%.

### CROSS-REFERENCE TO RELATED APPLICATIONS

This application is based on and claims priority under 35 U.S.C. § 119 to Japanese Patent Application No. 2024-119264, filed on Jul. 25, 2024, the entire content of which is incorporated herein by reference.

### TECHNICAL FIELD

This disclosure relates to a quartz crystal device, a quartz-crystal vibrating piece mounted on the quartz crystal device, and a crystal wafer in which a plurality of quartz-crystal vibrating pieces are formed.

### DESCRIPTION OF THE RELATED ART

Piezoelectric devices are widely used to mainly select or control frequencies in various kinds of electronic equipment, such as a mobile phone and a personal computer. The piezoelectric devices can be categorized into a piezoelectric resonator, a piezoelectric oscillator, a SAW device, an optical device, and the like depending on the functions. Quartz crystal devices, such as a crystal unit and a crystal oscillator, using a crystal as a piezoelectric element are widely known and generally used.

In recent years, such quartz crystal devices have been increasingly requested to be even smaller, and the photolithography technique and the wet etching technique are used. For example, Japanese Patent No. 6613482 discloses forming a crystal unit with a relatively low frequency by adjusting the shape of a crystal element while using the photolithography technique and the wet etching technique.

However, while a high-frequency crystal unit with a frequency exceeding 100 MHz is also requested to be smaller, it cannot be designed similarly to a crystal unit with a frequency of several tens of MHz. In particular, a crystal unit with a high frequency needs to have a thinned electrode film thickness compared with a crystal unit with a low frequency, and the thinned electrode film thickness has a problem of not being capable of sufficiently meeting a request of a low crystal impedance (hereinafter, referred to as a low CI).

A need thus exists for a quartz crystal device, a quartz-crystal vibrating piece, and a crystal wafer which are not susceptible to the drawback mentioned above.

### SUMMARY

According to one aspect of this disclosure, there is provided a quartz crystal device. The quartz crystal device includes a package, an AT-cut quartz-crystal vibrating piece, and a securing member. The package includes a bottom plate in a rectangular shape in plan view, a dike provided along an edge of the bottom plate, and an adhesion pad provided on one end side in a long-side direction in an inner region surrounded by the dike. The AT-cut quartz-crystal vibrating piece is in a rectangular shape in plan view. The quartz-crystal vibrating piece includes an excitation electrode, a pad electrode positioned on one end side in a long-side direction thereof, and an extraction electrode connecting the excitation electrode to the pad electrode. The excitation electrodes, the pad electrodes, and the extraction electrodes are formed on front and back surfaces. The securing member secures the quartz-crystal vibrating piece to the adhesion pad at a position where the pad electrode is opposed to the adhesion pad. A ratio of a width of the extraction electrode to a dimension in a short-side direction of the quartz-crystal vibrating piece is 15% or more and less than 50%.

According to one aspect of this disclosure, there is provided a quartz-crystal vibrating piece in a rectangular shape in plan view. The quartz-crystal vibrating piece includes excitation electrodes, a pad electrode, and an extraction electrode. The excitation electrodes are formed on front and back surfaces. The pad electrode is positioned on one end side in a long-side direction of the quartz-crystal vibrating piece. The extraction electrode connects the excitation electrode to the pad electrode. A ratio of a width of the extraction electrode to a dimension in a short-side direction of the quartz-crystal vibrating piece is 15% or more and less than 50%.

According to one aspect of this disclosure, there is provided a crystal wafer. The crystal wafer includes a plurality of quartz-crystal vibrating pieces, a framing portion, and a connection portion. The quartz-crystal vibrating piece includes excitation electrodes, a pad electrode, and an extraction electrode. The excitation electrodes are formed on front and back surfaces. The pad electrode is positioned on one end side in a long-side direction of the quartz-crystal vibrating piece. The extraction electrode connects the excitation electrode to the pad electrode. A ratio of a width of the extraction electrode to a dimension in a short-side direction of the quartz-crystal vibrating piece is 15% or more and less than 50%. The quartz-crystal vibrating piece is in a rectangular shape in plan view. The quartz-crystal vibrating piece is connected to the framing portion. The connection portion connects the respective quartz-crystal vibrating pieces to the framing portion.

With this disclosure, a quartz crystal device having characteristics of a low crystal impedance, a piezoelectric crystal element used therefor, and a crystal wafer formed of a plurality of quartz-crystal vibrating pieces are providable.

The above effect is only exemplary for the convenience of explanation, and effects according to this disclosure are not limited to the above. In addition to the above effect, this disclosure can provide any effect described in this disclosure.

### BRIEF DESCRIPTION OF THE DRAWINGS

The foregoing and additional features and characteristics of this disclosure will become more apparent from the following detailed description considered with reference to the accompanying drawings, wherein:

FIG. 1 is a perspective view of a crystal unit according to an embodiment;

FIG. 2A is an end view taken along the dash-dotted line IIA-IIA in FIG. 1, FIG. 2B is a top view of the crystal unit according to the embodiment, and FIG. 2C is an end view taken along the dash-dotted line IIC-IIC in FIG. 2A;

FIG. 3A is a side view of a quartz-crystal vibrating piece included in the crystal unit according to the embodiment, and FIG. 3B is a front surface view of the quartz-crystal vibrating piece included in the crystal unit according to the embodiment;

FIG. 4A is a side view of the quartz-crystal vibrating piece included in the crystal unit according to the embodiment, and FIG. 4B is a back surface view of the quartz-crystal vibrating piece included in the crystal unit according to the embodiment;

FIG. 5A is a graph showing a relation between an extraction wiring width and a prober CI in a crystal unit used for evaluation, and FIG. 5B is a graph showing the relation between the extraction wiring width and a wiring resistance in the crystal unit used for evaluation;

FIG. 6 is a graph showing a ratio of the extraction wiring width to a Z-direction dimension in the crystal unit used for evaluation;

FIG. 7 is a graph showing a ratio of the extraction wiring width to a pad electrode width of the Z-direction dimension in the crystal unit used for evaluation;

FIG. 8A is a plan view of a crystal wafer according to the embodiment, and FIG. 8B is an enlarged view of the region R1 in FIG. 8A; and

FIG. 9A is a back surface view of a state where a mesa portion is formed on each quartz-crystal vibrating piece of the crystal wafer according to the embodiment, and FIG. 9B is a plan view of a state where an electrode is formed on each quartz-crystal vibrating piece of the crystal wafer according to the embodiment.

### DETAILED DESCRIPTION

The following describes a crystal unit as one example of a quartz crystal device of this disclosure, a quartz-crystal vibrating piece of this disclosure, and a crystal wafer of this disclosure in detail with reference to the drawings. This disclosure is not limited to the contents described below and can be conveniently changed to the extent that the gist does not change. In addition, all the drawings used for the embodiment schematically illustrate the crystal unit, the quartz-crystal vibrating piece, and the crystal wafer according to this disclosure and are, for example, partially emphasized, enlarged, reduced, or omitted to deepen understanding. They might not accurately represent the reduced scale, shape, and the like of each component part. Furthermore, some numerical values used in the embodiment all indicate examples and can be changed variously as necessary. Then, identical reference numerals are attached to configurations common in the drawings.

### Structure of Crystal Unit

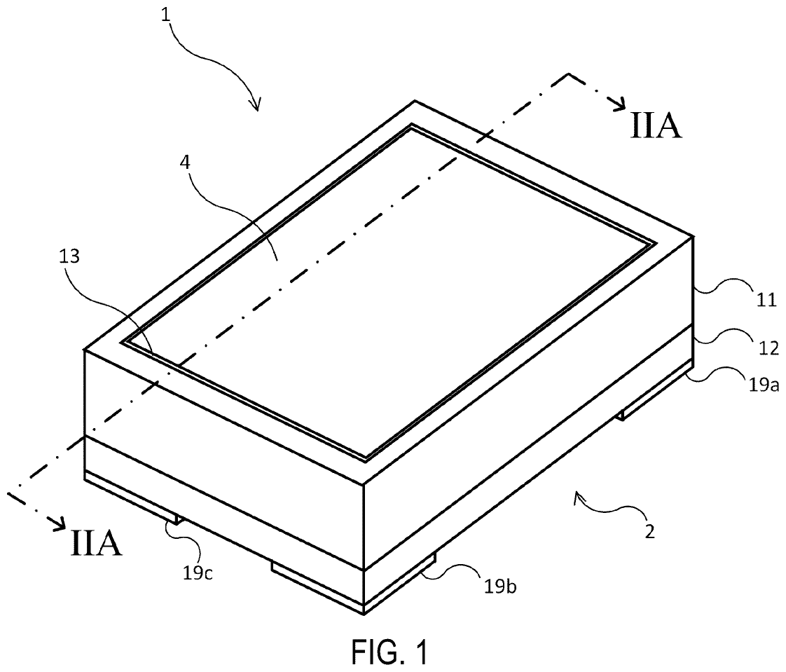

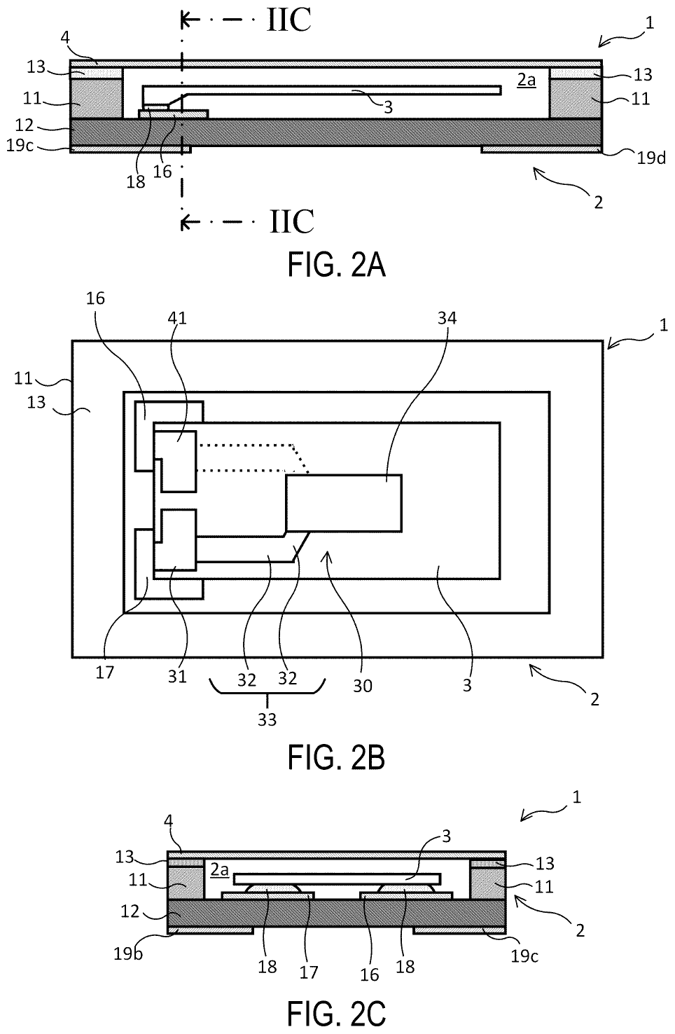

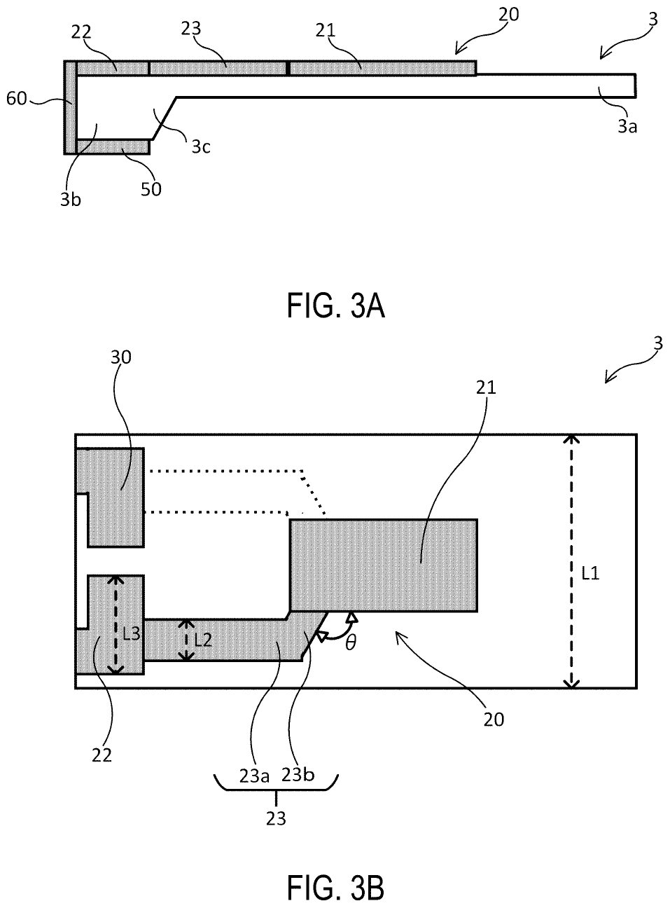

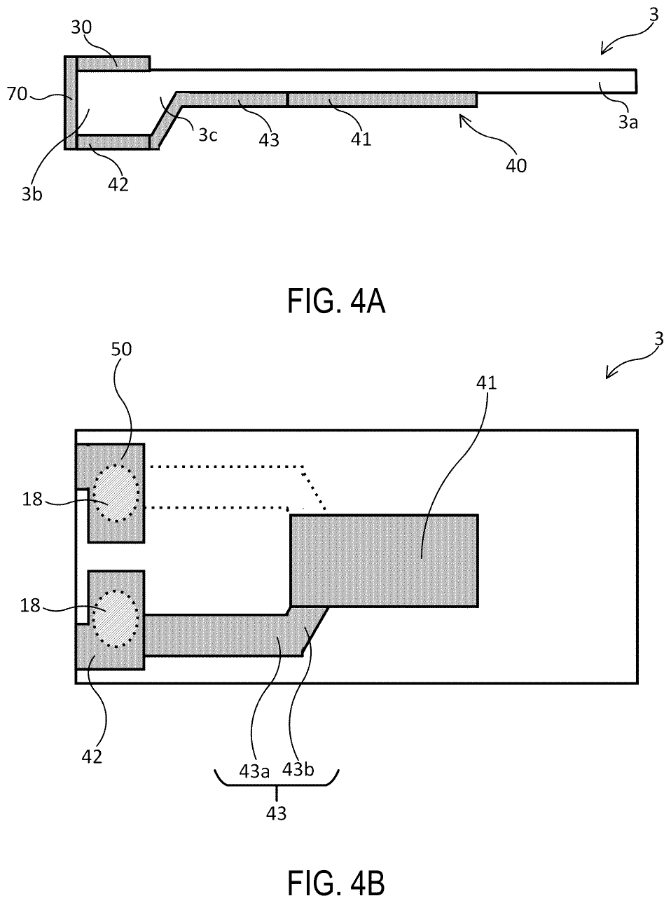

First, with reference to FIG. 1 to FIG. 4B, basic structures of a crystal unit and a quartz-crystal vibrating piece according to this disclosure will be described. FIG. 1 is a perspective view of the crystal unit according to an embodiment. FIG. 2A is an end view taken along the dash-dotted line IIA-IIA in FIG. 1, FIG. 2B is a top view of the crystal unit according to the embodiment, and FIG. 2C is an end view taken along the dash-dotted line IIC-IIC in FIG. 2A. FIG. 3A is a side view of the quartz-crystal vibrating piece included in the crystal unit according to the embodiment, and is especially a side view in one direction illustrating a connection configuration according to a front surface electrode of the quartz-crystal vibrating piece. FIG. 3B is a front surface view of the quartz-crystal vibrating piece included in the crystal unit according to the embodiment. FIG. 4A is a side view of the quartz-crystal vibrating piece included in the crystal unit according to the embodiment, and is especially a side view in another direction (the opposite side from the one direction) illustrating a connection configuration according to a back surface electrode of the quartz-crystal vibrating piece. FIG. 4B is a back surface view of the quartz-crystal vibrating piece included in the crystal unit according to the embodiment.

As can be seen from FIG. 1 and FIG. 2A to FIG. 2C, a crystal unit 1 as an exemplary quartz crystal device has a crystal resonator package 2 (hereinafter, simply referred to as the package 2), a quartz-crystal vibrating piece 3 mounted in a depressed-shaped mount space 2a of the package 2, and a metallic cover (lid) 4 for sealing the mount space 2a. The crystal unit 1 is an element that can generate a constant frequency by a piezoelectric phenomenon by a voltage application to the quartz-crystal vibrating piece 3 as an exemplary piezoelectric vibrating piece.

The package 2 is a ceramic package formed by stacking a plurality of ceramics with desired metal patterns formed on the surfaces. Specifically, the package 2 has a stacked structure in which an outer frame wall 11 as a dike having an opening in a predetermined dimension and a bottom plate 12 in a rectangular shape in plan view are stacked. Especially, the outer frame wall 11 is disposed along an edge of the bottom plate 12. With such a stacked structure, the package 2 has the mount space 2a having a depressed shape for mounting the quartz-crystal vibrating piece 3. On a front surface of the bottom plate 12 in the mount space 2a, a region for mounting the quartz-crystal vibrating piece 3 is formed, and an electrode pad described later is disposed in a peripheral area of the region.

Here, the shape of the package 2 is a rectangular parallelepiped shape, and is a rectangular shape in top view (FIG. 2B). Note that, hereinafter, a thickness direction of the crystal unit 1 and the package 2 is a vertical direction, and a direction perpendicular to this vertical direction is a horizontal direction. The horizontal direction may be classified into a long-side direction (longitudinal direction) and a short-side direction (lateral direction) of the crystal unit 1 and the package 2. Furthermore, a surface positioned on an upper side in the vertical direction is sometimes referred to as a front surface, and a surface positioned on a lower side is sometimes referred to as a back surface for each member.

The outer frame wall 11 of the package 2 has an exposed surface (a surface positioned on the upper side in the vertical direction) on which a conductor pattern 13 for sealing is formed. The conductor pattern 13 has a planar shape in a frame shape similarly to that of the outer frame wall 11. The cover 4 is bonded by known metal bonding on the conductor pattern 13. This seals the mount space 2a of the package, and the mount space 2a is sealed using a vacuum or a gas of nitrogen or the like.

The bottom plate 12 of the package 2 has an exposed surface (a surface positioned on the upper side in the vertical direction) on which two terminals 16, 17 for mounting a quartz-crystal vibrating piece as adhesion pads are formed. Especially, the terminals 16, 17 for mounting the quartz-crystal vibrating piece are disposed on one end side in the long-side direction in an inner region surrounded by the outer frame wall 11. Here, the terminals 16, 17 for mounting the quartz-crystal vibrating piece have the quartz-crystal vibrating piece 3 mounted via conductive adhesives 18. On the other hand, the bottom plate 12 of the package 2 has four corners on the back surface where four external connecting terminals 19a, 19b, 19c, 19d are formed. The terminals 16, 17 for mounting the quartz-crystal vibrating piece are electrically connected to the external connecting terminals 19a, 19b, 19c, 19d via connection wiring (not illustrated) internally disposed in the package 2.

As can be seen from FIG. 3A, FIG. 3B, FIG. 4A, and FIG. 4B, the quartz-crystal vibrating piece 3 is constituted of a flat-plate-shaped excitation portion 3a on one end side, a mesa portion 3b having a thickness larger than that of the excitation portion 3a on another end side, and an inclined portion 3c positioned between the excitation portion 3a and the mesa portion 3b. The quartz-crystal vibrating piece 3 is formed into a rectangular shape in plan view. Furthermore, as illustrated in FIG. 2B, the quartz-crystal vibrating piece 3 is mounted such that its long-side direction and a short-side direction are positioned along the long-side direction and the short-side direction of the crystal unit 1. In other words, the long-side direction of the quartz-crystal vibrating piece 3 corresponds to the long-side direction of the crystal unit 1, and the short-side direction of the quartz-crystal vibrating piece 3 also corresponds to the short-side direction of the crystal unit 1.

The excitation portion 3a is a portion that has a thickness corresponding to a frequency oscillated as the crystal unit 1 to generate a necessary vibration. In contrast to this, the mesa portion 3b is disposed to improve adhesive strength and adhesivity of the quartz-crystal vibrating piece 3. The inclined portion 3c has a shape in which a thickness thereof gradually increases from the excitation portion 3a toward the mesa portion 3b. This is a shape formed by characteristics of a crystalline structure of a crystal when a thickness of the excitation portion 3a is made a predetermined thickness by etching.

In the embodiment, the oscillation frequency of the crystal unit 1 is not particularly limited, but is preferred to be applied to a high frequency band element. The specific frequency is 100 MHz or more and 160 MHz or less. That is, when oscillated with a fundamental wave (n=1), the thickness of the quartz-crystal vibrating piece 3 (more specifically, the thickness of the excitation portion 3a) is assumed to be 8 μm or more and 16 μm or less. The crystal unit 1 having such a high frequency oscillation frequency has a small electrode diameter with respect to a chip size, and therefore, confinement of vibration energy is easy compared with the crystal unit having an oscillation frequency in a low frequency of less than 100 MHz, and designing the electrode as described later facilitates achieving a low crystal impedance (low CI).

Electrodes are formed on front and back surfaces of the quartz-crystal vibrating piece 3, and are capable of applying a voltage to the quartz-crystal vibrating piece 3. Specifically, as can be seen from FIG. 3A and FIG. 3B, a first front surface electrode 20 and a second front surface electrode 30 are formed on the front surface of the quartz-crystal vibrating piece 3. The first front surface electrode 20 is constituted of an excitation electrode 21 formed on a front surface of the excitation portion 3a, a pad electrode 22 formed on a front surface of the mesa portion 3b, and an extraction electrode 23 connecting the excitation electrode 21 to the pad electrode 22. Here, the extraction electrode 23 is constituted of a rectangular portion 23a extending toward the long-side direction of the quartz-crystal vibrating piece 3, and an inclined portion 23b inclined from the rectangular portion 23a toward the excitation electrode 21 and inclined with respect to the long-side direction of the quartz-crystal vibrating piece 3.

The second front surface electrode 30 is formed side by side with the pad electrode 22 on the front surface of the mesa portion 3b, and has a dimension and a shape identical to those of the pad electrode 22.

As can be seen from FIG. 4A and FIG. 4B, a first back surface electrode 40 and a second back surface electrode 50 are formed on the back surface of the quartz-crystal vibrating piece 3. The first back surface electrode 40 is constituted of an excitation electrode 41 formed on a back surface of the excitation portion 3a, a pad electrode 42 formed on a back surface of the mesa portion 3b, and an extraction electrode 43 connecting the excitation electrode 41 to the pad electrode 42. Here, the extraction electrode 43 is constituted of a rectangular portion 43a extending in the long-side direction of the quartz-crystal vibrating piece 3, and an inclined portion 43b inclined from the rectangular portion 43a toward the excitation electrode 41 and inclined with respect to the long-side direction of the quartz-crystal vibrating piece 3.

As can be seen from FIG. 3B and FIG. 4A, the pad electrode 42 is formed to be opposed to the second front surface electrode 30 formed on the front surface side of the quartz-crystal vibrating piece 3. Furthermore, the second back surface electrode 50 is formed side by side with the pad electrode 42 on the back surface of the mesa portion 3b, and has a dimension and a shape identical to those of the pad electrode 42. Furthermore, as can be seen from FIG. 3A, FIG. 3B, and FIG. 4B, the second back surface electrode 50 is formed to be opposed to the pad electrode 22 formed on the front surface side of the quartz-crystal vibrating piece 3.

As illustrated in FIG. 3A, the first front surface electrode 20 formed on the front surface side of the quartz-crystal vibrating piece 3 is electrically connected to the second back surface electrode 50 via a side surface electrode 60 formed on a side surface of the quartz-crystal vibrating piece 3. Meanwhile, as illustrated in FIG. 4A, the first back surface electrode 40 formed on the back surface side of the quartz-crystal vibrating piece 3 is electrically connected to the second front surface electrode 30 via a side surface electrode 70 formed on the side surface of the quartz-crystal vibrating piece 3.

Here, as illustrated in FIG. 4B, the conductive adhesives 18 are positioned on the pad electrode 42 of the first back surface electrode 40 and on the second back surface electrode 50, and the quartz-crystal vibrating piece 3 is secured to the terminals 16, 17 for mounting the quartz-crystal vibrating piece via the conductive adhesives 18. That is, at the positions where the mesa portion 3b is opposed to the terminals 16, 17 for mounting the quartz-crystal vibrating piece, the mesa portion 3b is adhered to the terminals 16, 17 for mounting the quartz-crystal vibrating piece via the conductive adhesives 18.

In this embodiment, the following electrode design is employed on the basis of the evaluation result of the crystal unit 1 described later, and thus, the low CI of the crystal unit 1 is achieved. Specifically, in FIG. 3B, the ratio of a width (L2) of the rectangular portion 23a of the extraction electrode 23 to a dimension (L1) in the short-side direction of the quartz-crystal vibrating piece 3 is preferred to be 15% or more and less than 50%. More preferably, the ratio of the width (L2) of the rectangular portion 23a of the extraction electrode 23 to the dimension (L1) in the short-side direction of the quartz-crystal vibrating piece 3 is 18% or more and 30% or less. Furthermore, in addition to the above-described condition, the ratio of the width (L2) of the rectangular portion 23a of the extraction electrode 23 to a dimension (L3) of a width of the pad electrode 22 in the short-side direction of the quartz-crystal vibrating piece 3 is preferred to be 32% or more and 70% or less.

In FIG. 3B, an angle θ formed by the excitation electrode 21 and the inclined portion 23b of the extraction electrode 23 is preferred to be 60 degrees or more and 70 degrees or less, and is especially preferred to be 61 degrees or more and 65 degrees or less. Here, the formed angle θ is an angle at which one side (a straight line along the inclined portion 23b) of a side portion of the inclined portion 23b intersects with one side in a long-side direction of the excitation electrode 21. To put these in other words, when defined as the angle θ with respect to the X-axis of the crystallographic axis of the crystal, an inclination angle of the inclined portion 23b is preferred to be 60 degrees or more and 70 degrees or less, and is especially preferred to be 61 degrees or more and 65 degrees or less.

Obviously, the electrodes on the front and back surfaces of the quartz-crystal vibrating piece 3 have the identical dimensions, and therefore, the ratio of the width of the rectangular portion 43a of the extraction electrode 43 to the dimension (L1) in the short-side direction of the quartz-crystal vibrating piece 3 is also similar to the design on the front surface side. The ratio of the width of the rectangular portion 43a of the extraction electrode 43 to the dimension of the width of the pad electrode 42 in the short-side direction of the quartz-crystal vibrating piece 3 is also similar to the design on the front surface side. Furthermore, the angle formed by the excitation electrode 41 and the inclined portion 43b of the extraction electrode 43 is also similar to the design on the front surface side.

### Electrode Evaluation of Crystal Unit

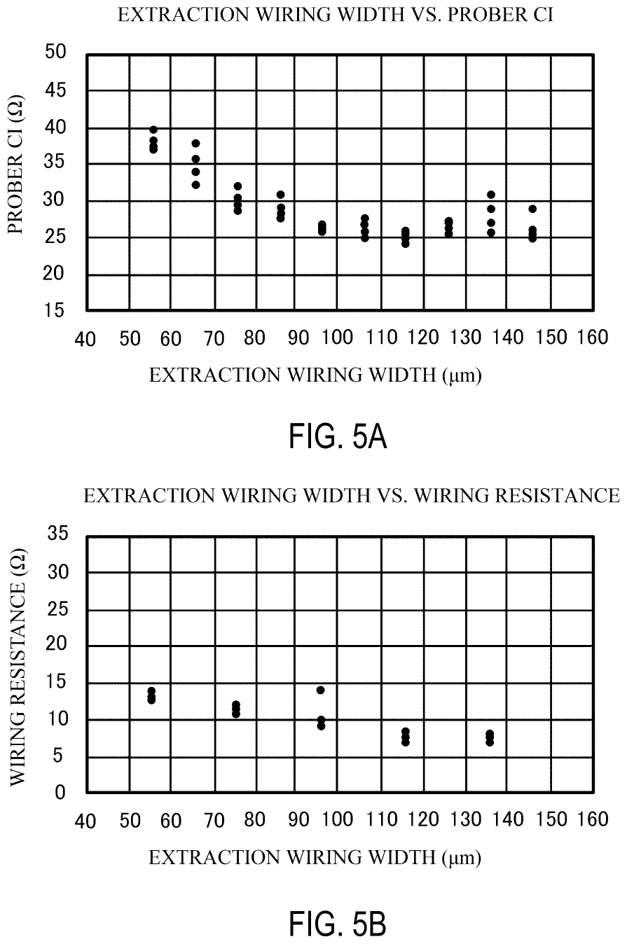

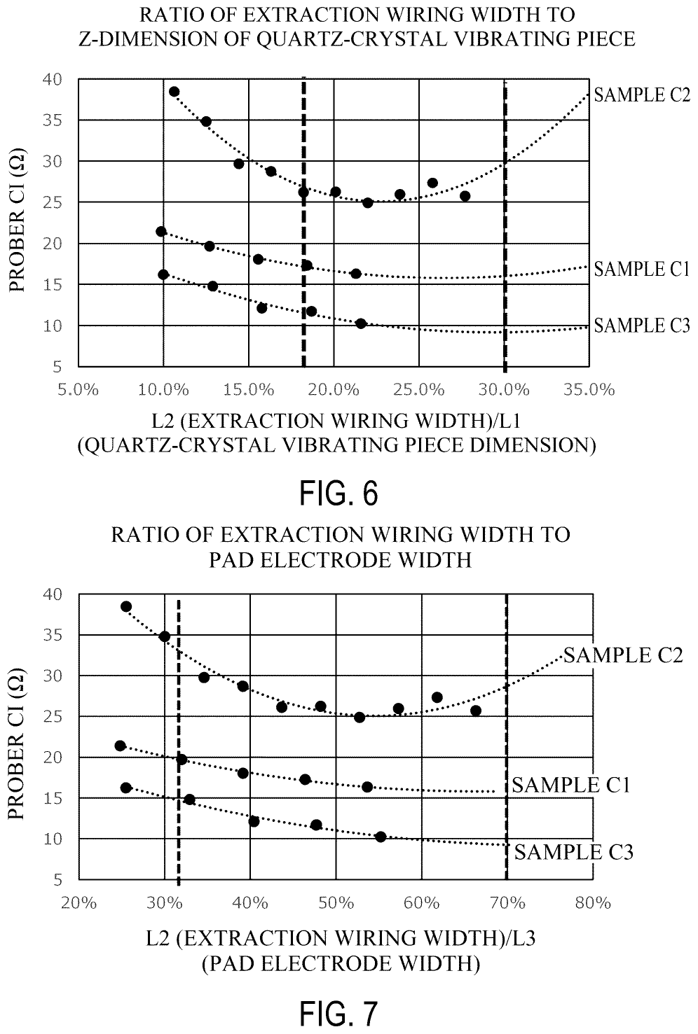

Next, on the basis of FIG. 5A, FIG. 5B, FIG. 6, and FIG. 7, an electrode evaluation of the crystal unit executed for leading the above-described electrode design will be described. Here, FIG. 5A is a graph showing a relation between an extraction wiring width and a prober CI in the crystal unit used for the evaluation. FIG. 5B is a graph showing a relation between the extraction wiring width and a wiring resistance in the crystal unit used for the evaluation. Furthermore, FIG. 6 is a graph showing a ratio of the extraction wiring width to a Z-direction dimension in the crystal unit used for the evaluation. FIG. 7 is a graph showing a ratio of the extraction wiring width to a width of the electrode pad of the Z-direction dimension in the crystal unit used for the evaluation.

First, three types as shown in Table 1 below were prepared as the prepared crystal units (samples).

TABLE 1
Types of prepared crystal units

| Frequency | 125 MHz | | 153.6 MHz | | 156.25 MHz | |
|---|---|---|---|---|---|---|
| Crystal unit size | 1.6 mm × | | 1.0 mm × | | 1.6 mm × | |
| | 1.2 mm | | 0.8 mm | | 1.2 mm | |
| X-dimension | 1062.4 | μm | 753.7 | μm | 1062.0 | μm |
| Z-dimension (L1) | 700.0 | μm | 527.3 | μm | 690.7 | μm |
| Width of pad electrode (L3) | 278.0 | μm | 220.0 | μm | 270.0 | μm |

| | | | |
|---|---|---|---|
| Inclined electrode angle θ | 61° | 65° | 62° |

Here, the crystal unit size is an outside dimension of the package. The X-dimension is a dimension in the long-side direction of the quartz-crystal vibrating piece, and the Z-dimension (L1) is a dimension in the short-side direction of the quartz-crystal vibrating piece. Furthermore, the width (L3) of the pad electrode is a dimension of the pad electrode in the short-side direction (that is, the Z-direction) of the quartz-crystal vibrating piece.

For the crystal unit (sample C1) with a frequency of 125 MHz as a sample of a first type, the width (L2) of the rectangular portion of the extraction electrode was adjusted as the width of the extraction electrode, and 30 to 32 pieces of each of five types with widths of 69 μm, 89 μm, 109 μm, 129 μm, and 149 μm were prepared as in Table 2 below.

TABLE 2
Crystal unit with 125 MHz

| Width of extraction electrode (L2) | L2/L1 (%) | L2/L3 (%) | CI (Ω) |
|---|---|---|---|
| 69 | 9.9 | 24.8 | 21.4 |
| 89 | 12.7 | 32.0 | 19.7 |
| 109 | 15.6 | 39.2 | 18.1 |
| 129 | 18.4 | 46.4 | 17.3 |
| 149 | 21.3 | 53.6 | 16.3 |

Here, L2/L1 (%) is a ratio of the width of the rectangular portion of the extraction electrode to the dimension in the short-side direction of the quartz-crystal vibrating piece. L2/L3 (%) is a ratio of the width of the extraction electrode to the width of the pad electrode. Furthermore, CI (Ω) is a value measured in a photo-wafer state before assembly adjustment as a crystal unit using an impedance analyzer, and is a median of the plurality of samples.

For the crystal unit (sample C2) with a frequency of 153.6 MHz as a sample of a second type, the width (L2) of the rectangular portion of the extraction electrode was adjusted as the width of the extraction electrode, and 500 to 600 pieces of each of ten types with widths of 56 μm, 66 μm, 76 μm, 86 μm, 96 μm, 106 μm, 116 μm, 126 μm, 136 μm, and 146 μm were prepared as in Table 3 below.

TABLE 3
Crystal unit with 153.6 MHz

| Width of extraction electrode (L2) | L2/L1 (%) | L2/L3 (%) | CI (Ω) |
|---|---|---|---|
| 56 | 10.6 | 25.5 | 38.5 |
| 66 | 12.5 | 30.0 | 34.8 |
| 76 | 14.4 | 34.5 | 29.7 |
| 86 | 16.3 | 39.1 | 28.8 |
| 96 | 18.2 | 43.6 | 26.2 |
| 106 | 20.1 | 48.2 | 26.2 |
| 116 | 22.0 | 52.7 | 24.9 |
| 126 | 23.9 | 57.3 | 25.9 |
| 136 | 25.8 | 61.8 | 27.3 |
| 146 | 27.7 | 66.4 | 25.7 |

For the crystal unit (sample C3) with a frequency of 156.25 MHz as a sample of a third type, the width (L2) of the rectangular portion of the extraction electrode was adjusted as the width of the extraction electrode, and 30 to 32 pieces of each of five types with widths of 69 μm, 89 μm, 109 μm, 129 μm, and 149 μm were prepared as in Table 4 below.

TABLE 4
Crystal unit with 156.25 MHz

| Width of extraction electrode (L2) | L2/L1 (%) | L2/L3 (%) | CI (Ω) |
|---|---|---|---|
| 69 | 10.0 | 25.6 | 16.3 |
| 89 | 12.9 | 33.0 | 14.8 |
| 109 | 15.8 | 40.4 | 12.1 |
| 129 | 18.7 | 47.8 | 11.8 |
| 149 | 21.6 | 55.2 | 10.3 |

Next, as illustrated in FIG. 5A, the horizontal axis indicates the extraction wiring width (μm), the vertical axis indicates the prober CI (Ω), and an effect of the extraction wiring width on the prober CI was examined for the sample C2 (153.6 MHz). Note that, in FIG. 5A, four samples are plotted for each extraction wiring width.

As can be seen from FIG. 5A, increasing the extraction wiring width decreases the prober CI. In particular, at an extraction wiring width of 96 μm or more, a change in the prober CI is reduced, and the prober CI is a constant value of approximately 25Ω.

Next, as illustrated in FIG. 5B, the horizontal axis indicates the extraction wiring width (μm), the vertical axis indicates the wiring resistance (Ω), and an effect of the extraction wiring width on the wiring resistance was examined for the sample C2 (153.6 MHz). Here, since the value of the wiring resistance was microscopic, the wiring resistance was measured by the 4-terminal method. For a more specific wiring resistance measurement, a resistance between the pad electrode and a distal end portion of the excitation electrode (a position that is separated further from the pad electrode in the long-side direction of the quartz-crystal vibrating piece) was measured using a semiconductor analyzer. Note that, in FIG. 5B, three samples are plotted for each extraction wiring width of 56 μm, 76 μm, 96 μm, 116 μm, and 136 μm.

As can be seen from FIG. 5B, increasing the extraction wiring width decreases the wiring resistance. In particular, at an extraction wiring width of 96 μm or more, a change in the wiring resistance is reduced, and the tendency to a constant value of approximately 10Ω is assumed. This is presumed to be because an increased size of extraction wiring reduces the volume resistivity of a thin film of gold that is one example of an electrode material.

From the results of FIG. 5A and FIG. 5B, it is seen that making the extraction wiring width a certain dimension or more allows reducing the CI value as the crystal unit and allows the value to be a value with a small change. In other words, making the extraction wiring width a certain dimension or more allows reducing a variation in the CI value caused by a variation in the electrode dimension generated during the production of the crystal unit.

Next, on the basis of the consideration of the results of FIG. 5A and FIG. 5B described above, there was performed an examination of how to adjust the extraction electrode width to successfully reduce the CI value of the crystal unit not by the dimensions of the crystal unit and the quartz-crystal vibrating piece, and furthermore, not by the frequency (that is, the thickness) of the crystal unit. Specifically, a relation between the extraction electrode width and the Z-dimension (the dimension in the short-side direction) of the quartz-crystal vibrating piece and a relation between the extraction electrode width and the pad electrode width were evaluated on the basis of the samples of the above-described three types of frequencies.

First, as illustrated in FIG. 6, the horizontal axis indicates a value obtained by dividing the extraction wiring width (L2) by the Z-dimension of the quartz-crystal vibrating piece, the vertical axis indicates the prober CI (Ω), and an effect of a ratio of the extraction electrode width to the Z-dimension of the quartz-crystal vibrating piece on the prober CI was examined for the respective samples (C1, C2, C3). Note that, in FIG. 6, a value of L2/L1 (%) in Table 2 to Table 4 described above is plotted for each sample. In FIG. 6, approximated curves (shown by dashed lines) based on plotting of the respective samples (C1, C2, C3) are also shown.

As can be seen from FIG. 6, the prober CI is reduced as the value of L2/L1 increases from 10% or more for all the samples. Especially, for the sample C2, the variation in the prober CI is reduced to have a prober CI of approximately 30Ω or less when the value of L2/L1 is 15% or more, and the prober CI becomes a constant value (approximately 26Ω) when the value of L2/L1 is 18% or more. The sample C1 and the sample C3 are also said to have a reduced variation in the prober CI when the value of L2/L1 is 15% or more.

Meanwhile, according to the approximated curve of the sample C2, the value of the prober CI tends to be increased when the value of L2/L1 is increased to exceed 25%. Especially, the value of the prober CI becomes 30Ω or more when the value of L2/L1 exceeds 30%, and the variation thereof is also increased. According to the respective approximated curves, the sample C1 and the sample C3 also have a tendency to an increased value of the prober CI when the value of L2/L1 exceeds 30%. However, the sample C1 and the sample C3 do not have a tendency to an increased variation in the prober CI like the sample C2 even when the value of L2/L1 exceeds 30%.

From such a result, L2/L1=15%, where the variation in the value of the prober CI becomes small, is set as the preferred lower limit of L2/L1. Taking a vibration energy leakage into consideration, approximately half of the dimension in the short-side direction of the quartz-crystal vibrating piece is presumed to be the limit of the extraction electrode dimension, and L2/L1=50% is set as the preferred upper limit of L2/L1. The range in which the value of the prober CI becomes a constant value is presumed to be more preferable, and L2/L1 is set to 18% or more and 30% or less as a more preferable range.

Next, as illustrated in FIG. 7, the horizontal axis indicates a value obtained by dividing the extraction wiring width (L2) by the pad electrode width (L3), the vertical axis indicates the prober CI (Ω), and an effect of a ratio of the extraction electrode width to the pad electrode width on the prober CI was examined for the respective samples (C1, C2, C3). Note that, in FIG. 7, a value of L2/L3 (%) in Table 2 to Table 4 described above is plotted for each sample. In FIG. 7, approximated curves (shown by dashed lines) based on plotting of the respective samples (C1, C2, C3) are also shown.

As can be seen from FIG. 7, the prober CI is reduced as the value of L2/L3 increases from 25% or more for all the samples. Especially, for the sample C2, the variation in the prober CI is reduced to have a prober CI of approximately 30Ω or less when the value of L2/L3 is 34% or more, and the prober CI becomes a constant value (approximately 26Ω) when the value of L2/L3 is 43% or more. The sample C1 and the sample C3 are also said to have a reduced variation in the prober CI when the value of L2/L3 is 25% or more, and said to have a reduced variation in the prober CI when the value of L2/L3 is 32% or more.

Meanwhile, according to the approximated curve of the sample C2, the value of the prober CI tends to be increased when the value of L2/L3 is increased to exceed 60%. Especially, the value of the prober CI becomes 28Ω or more when the value of L2/L3 exceeds 70%, and the variation thereof is also increased. According to the respective approximated curves, the sample C1 and the sample C3 have a tendency to a reduced value of the prober CI when the value of L2/L3 is up to 70%.

From such a result, the range in which the value of the prober CI becomes a constant value is presumed to be a preferable range, and L2/L3 is set to 32% or more and 70% or less as the preferable range. As a range in which the value of the prober CI becomes more stable, the range of 40% or more and 60% or less of L2/L3 has been found more preferable.

### Producing Method

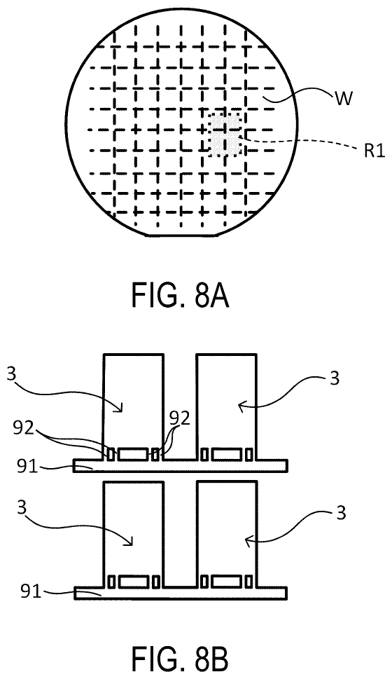

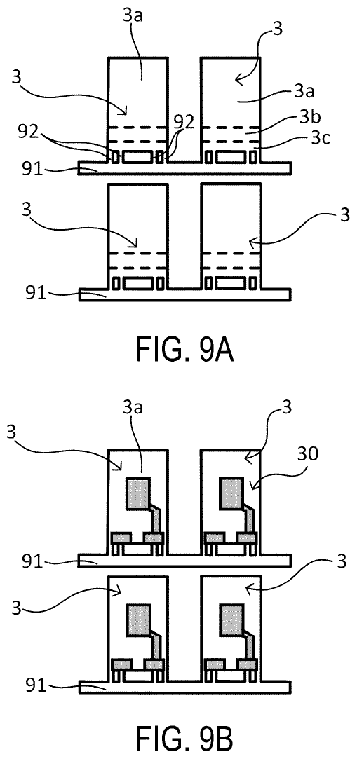

Next, with reference to FIG. 8 and FIG. 9, a production method of a crystal wafer W and the quartz-crystal vibrating piece 3 according to this disclosure will be described. Here, FIG. 8A is a plan view of the crystal wafer W according to the embodiment. FIG. 8B is an enlarged view of the region R1 in FIG. 8A. Furthermore, FIG. 9A is a back surface view of a state where the mesa portions 3b are formed on the respective quartz-crystal vibrating pieces 3 of the crystal wafer W according to the embodiment. FIG. 9B is a plan view of a state where the electrodes are formed on the respective quartz-crystal vibrating pieces 3 of the crystal wafer W according to the embodiment.

First, the crystal wafer W having a planar shape in an approximately circular shape as illustrated in FIG. 8A is prepared. For example, a type of cut from a crystal bar is an AT-cut. However, the planar shape is not limited to the circular shape, and may be a square shape, and the cut is not limited to the AT-cut, and may be another cut including a double rotation cut, such as a Z-cut or a SC-cut.

Next, metal films are formed on front and back surfaces of the crystal wafer W to form an etching resist mask. Subsequently, the metal films are processed by a well-known photolithography technique, and the etching resist mask for forming an outer shape of the quartz-crystal vibrating piece 3 is formed on the front and back surfaces of the crystal wafer W. In the case of the embodiment, the etching resist mask has a structure that corresponds to a portion corresponding to the outer shape of the quartz-crystal vibrating piece 3, framing portions 91 (see FIG. 8B) formed to surround the plurality of quartz-crystal vibrating pieces 3, and a plurality of connection portions 92 (see FIG. 8B) connecting the framing portions 91 to the respective quartz-crystal vibrating pieces 3. Thereafter, the crystal wafer W on which the etching resist mask has been formed is immersed in an etchant made mainly of a hydrofluoric acid for a predetermined period. This process causes a portion of the crystal wafer W not covered with the etching resist mask to be dissolved, and a rough outer shape of the quartz-crystal vibrating piece 3 is obtained as illustrated in FIG. 8B. Note that the quantity of the connection portions 92 for each of the quartz-crystal vibrating pieces 3 is not limited to four as in FIG. 8B, may be two, three, or five or more, and furthermore, may be one.

Next, the etching resist mask is removed from the crystal wafer W. At this time, only parts of the etching resist mask corresponding to the excitation portion 3a and the inclined portion 3c of the quartz-crystal vibrating piece 3 are removed, and parts corresponding to the mesa portion 3b of the quartz-crystal vibrating piece 3 and the framing portion 91 and the connection portion 92 of the crystal wafer W are left. This enables forming the inclined portion 3c positioned between the excitation portion 3a and the mesa portion 3b and ensuring the strength of the framing portion 91 and the connection portion 92.

Next, the crystal wafer W in a state where the parts of the etching resist mask are removed is immersed in the etchant made mainly of a hydrofluoric acid for a predetermined period again. Here, the predetermined period is a period that it takes for a thickness of a formation-scheduled region of the excitation portion 3a of the quartz-crystal vibrating piece 3 to be a thickness that can fulfil the specification of the oscillation frequency required. Between the excitation portion 3a and the mesa portion 3b, an amount of being etched is gradually increased toward the excitation portion 3a due to the crystalline structure of the crystal wafer W, and thus, the inclined portion 3c is formed (see FIG. 9A).

Next, the etching resist mask is removed from the crystal wafer W on which the above-described etching is terminated, and the whole surfaces of the crystal wafer W are exposed. Thereafter, metal films for the respective electrodes of the quartz-crystal vibrating piece 3 are formed by a well-known film formation method on the whole surfaces (the front and back surfaces) of the crystal wafer W. Subsequently, the metal films are patterned into an electrode shape by a well-known photolithography technique and metal etching technique, and thus, the respective electrodes are formed on the front and back surfaces of the crystal wafer Was illustrated in FIG. 3B, FIG. 4B, and FIG. 9B. Thereafter, cutting at the connection portions 92 or removing the connection portions 92 separates the respective quartz-crystal vibrating pieces 3 from the framing portions 91 to be individualized. This completes the formation of the quartz-crystal vibrating piece 3 in the state where the electrode is formed.

Note that cutting and removing of the connection portions 92 may be performed by etching, or may be performed mechanically. When they are performed mechanically, finishing, such as etching to remove unnecessary portions, may be performed on the quartz-crystal vibrating piece 3.

### Modification of Embodiment

While in the above-described embodiment, the crystal unit has been described as one example of the quartz crystal device, it is not limited to this. That is, the quartz crystal device of this disclosure may be a crystal controlled oscillator in which the quartz-crystal vibrating piece 3 of the embodiment is mounted. In this case, the crystal controlled oscillator may have a structure in which the quartz-crystal vibrating piece 3 is mounted in the same space as an IC chip, or may have an H-shaped structure in which the quartz-crystal vibrating piece 3 is opposed to the IC chip via the bottom plate.

While in the above-described embodiment, the frequency of the crystal unit 1 is set to a high frequency of 100 MHz or more, it is not limited to this, and may be a low frequency of several tens of MHz. Even in such a case, by employing the above-described electrode design, it is presumed that a low crystal impedance is achievable.

Furthermore, while in the above-described embodiment, the mesa portion 3b and the inclined portion 3c are disposed at one end of the quartz-crystal vibrating piece 3, they do not necessarily have to be disposed. That is, the shape of the quartz-crystal vibrating piece 3 may be a flat plate having a thickness of the excitation portion 3a. When the frequency of the crystal unit 1 is several tens of MHz, both ends of the quartz-crystal vibrating piece 3 may be in an inclined and thinning shape.

### Aspects of Disclosure

A first embodiment of this disclosure provides the quartz crystal device including a package, an AT-cut quartz-crystal vibrating piece, and a securing member. The package includes a bottom plate in a rectangular shape in plan view, a dike provided along an edge of the bottom plate, and an adhesion pad provided on one end side in a long-side direction in an inner region surrounded by the dike. The AT-cut quartz-crystal vibrating piece is in a rectangular shape in plan view. The quartz-crystal vibrating piece includes an excitation electrode, a pad electrode positioned on one end side in a long-side direction thereof, and an extraction electrode connecting the excitation electrode to the pad electrode. The excitation electrodes, the pad electrodes, and the extraction electrodes are formed on front and back surfaces. The securing member secures the quartz-crystal vibrating piece to the adhesion pad at a position where the pad electrode is opposed to the adhesion pad. A ratio of a width of the extraction electrode to a dimension in a short-side direction of the quartz-crystal vibrating piece is 15% or more and less than 50%.

Such a ratio of the width of the extraction electrode to the dimension in the short-side direction of the quartz-crystal vibrating piece allows reducing the wiring resistance of the electrode, and reducing the crystal impedance of the crystal unit.

In a second embodiment of this disclosure, which is in the first embodiment, the ratio of the width of the extraction electrode to the dimension in the short-side direction of the quartz-crystal vibrating piece is 18% or more and 30% or less.

This causes the wiring resistance of the electrode to be further reduced and stabilized, and thus, allows reducing the crystal impedance of the crystal unit and also the variation thereof.

In a third embodiment of this disclosure, which is in the first or the second embodiment, a ratio of the width of the extraction electrode to a dimension of a width of the pad electrode in the short-side direction of the quartz-crystal vibrating piece is 32% or more and 70% or less.

This causes the wiring resistance of the electrode to be further reduced and stabilized, and thus, allows reducing the crystal impedance of the crystal unit and also the variation thereof.

In a fourth embodiment of this disclosure, which is in any one of the first to the third embodiment, the quartz-crystal vibrating piece has a thickness of 8 μm or more and 16 μm or less.

This allows the frequency of the crystal unit to be 100 MHz or more, and allows providing the crystal unit with a high frequency having characteristics of a low crystal impedance.

In a fifth embodiment of this disclosure, which is in any one of the first to the fourth embodiment, the extraction electrode includes a rectangular portion extending from the pad electrode in the long-side direction of the quartz-crystal vibrating piece, and an inclined portion inclined from the rectangular portion toward the excitation electrode and inclined with respect to the long-side direction of the quartz-crystal vibrating piece.

This causes the wiring resistance of the electrode to be further reduced and stabilized, and thus, allows reducing the crystal impedance of the crystal unit and also the variation thereof.

A sixth embodiment of this disclosure provides the quartz-crystal vibrating piece in a rectangular shape in plan view. The quartz-crystal vibrating piece includes excitation electrodes, a pad electrode, and an extraction electrode. The excitation electrodes are formed on front and back surfaces. The pad electrode is positioned on one end side in a long-side direction of the quartz-crystal vibrating piece. The extraction electrode connects the excitation electrode to the pad electrode. A ratio of a width of the extraction electrode to a dimension in a short-side direction of the quartz-crystal vibrating piece is 15% or more and less than 50%.

Such a ratio of the width of the extraction electrode to the dimension in the short-side direction of the quartz-crystal vibrating piece allows reducing the wiring resistance of the electrode, and reducing the crystal impedance of the crystal unit.

A seventh embodiment of this disclosure provides the crystal wafer including a plurality of the quartz-crystal vibrating pieces of the sixth embodiment, a framing portion to which the quartz-crystal vibrating piece is connected, and a connection portion that connects the respective quartz-crystal vibrating pieces to the framing portion.

This enables simultaneously forming and supplying a plurality of piezoelectric vibrating pieces.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A quartz crystal device comprising:
a package including a bottom plate in a rectangular shape in plan view, a dike provided along an edge of the bottom plate, and an adhesion pad provided on one end side in a long-side direction in an inner region surrounded by the dike;
an AT-cut quartz-crystal vibrating piece in a rectangular shape in plan view, the quartz-crystal vibrating piece including an excitation electrode, a pad electrode positioned on one end side in a long-side direction thereof, and an extraction electrode connecting the excitation electrode to the pad electrode, the excitation electrodes, the pad electrodes, and the extraction electrodes being formed on front and back surfaces; and
a securing member that secures the quartz-crystal vibrating piece to the adhesion pad at a position where the pad electrode is opposed to the adhesion pad, wherein
a ratio of a width of the extraction electrode to a dimension in a short-side direction of the quartz-crystal vibrating piece is 15% or more and less than 50%.

2. The quartz crystal device according to claim 1, wherein
the ratio of the width of the extraction electrode to the dimension in the short-side direction of the quartz-crystal vibrating piece is 18% or more and 30% or less.

3. The quartz crystal device according to claim 1, wherein
a ratio of the width of the extraction electrode to a dimension of a width of the pad electrode in the short-side direction of the quartz-crystal vibrating piece is 32% or more and 70% or less.

4. The quartz crystal device according to claim 1, wherein
the quartz-crystal vibrating piece has a thickness of 8 μm or more and 16 μm or less.

5. The quartz crystal device according to claim 1, wherein
the extraction electrode includes a rectangular portion extending from the pad electrode in the long-side direction of the quartz-crystal vibrating piece, and an inclined portion inclined from the rectangular portion toward the excitation electrode and inclined with respect to the long-side direction of the quartz-crystal vibrating piece.

6. A quartz-crystal vibrating piece in a rectangular shape in plan view, comprising:
excitation electrodes formed on front and back surfaces;
a pad electrode positioned on one end side in a long-side direction of the quartz-crystal vibrating piece; and
an extraction electrode connecting the excitation electrode to the pad electrode, wherein
a ratio of a width of the extraction electrode to a dimension in a short-side direction of the quartz-crystal vibrating piece is 15% or more and less than 50%.

7. A crystal wafer comprising:
a plurality of the quartz-crystal vibrating pieces according to claim 6;
a framing portion to which the quartz-crystal vibrating piece is connected; and
a connection portion that connects the respective quartz-crystal vibrating pieces to the framing portion.
